(19) United States
(12) Patent Application Publication
(10) Pub. No.: US 2016/0094209 A1
(43) Pub. Date: Mar. 31, 2016

(54) METHOD AND CIRCUIT FOR ELIMINATING TRANSFORMER SATURATION IN THE PRESENCE OF DC OFFSET VOLTAGE

(71) Applicant: Liebert Corporation, Columbus, OH (US)

(72) Inventors: Terry D. BUSH, Westerville, OH (US); Charles DUNN, Worthington, OH (US); James MILLER, Fredericktown, OH (US); Charles F. BLAIR, Powell, OH (US)

(73) Assignee: LIEBERT CORPORATION, Columbus, OH (US)

(21) Appl. No.: 14/851,295

(22) Filed: Sep. 11, 2015

Related U.S. Application Data
(60) Provisional application No. 62/056,636, filed on Sep. 29, 2014.

(51) Int. Cl. H03K 5/003; H03K 17/74

(52) U.S. Cl. CPC H03K 5/003; H03K 17/74

(57) ABSTRACT

A DC offset voltage in an AC input voltage to a transformer and associated saturation current are eliminated by the placement of an anti-parallel diode pair circuit in series between a source of the AC input voltage and a primary winding of the transformer. The anti-parallel diode pair circuit has an input coupled to an output by parallel connected oppositely biased branch diode circuits. Each branch diode circuit has at least one diode where the diode of one such branch diode circuit is biased in one direction and the diode of the other such branch diode circuit is biased in an opposite direction and each branch diode circuit has the same number of diodes as the other branch diode circuit.

This application claims the benefit of U.S. Provisional Application No. 62/056,636 filed on Sep. 29, 2014. The entire disclosure of the above application is incorporated herein by reference.

### FIELD

The present disclosure relates to elimination of a transformer saturation current in the presence of a DC offset voltage in an AC input voltage to the transformer.

### BACKGROUND

This section provides background information related to the present disclosure which is not necessarily prior art.

Magnetic flux of a core of a transformer is directly proportional to the volt-seconds (time integral of voltage) applied to the primary winding of the transformer. The term “core” as used herein means the core of a transformer. The flux direction (polarity) alternates positive and negative just as the integral of the voltage applied does. Depending on the design, a given core can only contain a limited flux density. If the flux density reaches this limit, the core becomes “saturated” in the sense that no more flux can be created in the core, even if voltage continues to be applied. This can happen for several reasons, for example if higher than rated voltage is applied to the transformer. When this occurs, the impedance of the primary winding of the transformer becomes very small because the counter-EMF (electro-magnetic-force) induced by the normally changing magnetic field no longer exists. It is this counter-EMF voltage which opposes the applied voltage and normally limits the current in the primary winding of the transformer.

If the AC voltage applied to the transformer also has a DC voltage (such as a DC offset voltage), the DC voltage as it is integrated over time would theoretically eventually drive the core to saturation even if the DC voltage is very small,. In practice, this will depend on the “permeability” of the core material, a measure of how easily a material can become magnetized. “Air core” transformers for example, having no magnetic core material, have a very high permeability and will not saturate. Many practical transformers (E-I cores for example) have an intentional air gap inserted within the core material and do not saturate easily. For these transformers some small amount of DC voltage can be tolerated due to the effective flux “loses” created by the air gap. This is also true for “cut C” core toroidal transformers (the cut inserts an air gap). However, continuous wound toroidal transformers have no gap and virtually no flux losses and therefore can tolerate almost no DC without saturating to some degree.

With reference to FIG. 1, the “BH” curve of FIG. 1 shows how core permeability affects the relationship between magnetic field strength H (created by the applied voltage and current flowing in the transformer windings) and magnetic flux density B (flux in the transformer core) for continuous toroidal cores, E-I cores and cut-C toroidal cores. This curve shows that as magnetic field strength H increases, the flux density B increases but reaches a maximum saturation level where increased magnetic field strength does not further increase flux density (for illustrative purposes, the curves for each core type have been normalized to the same maximum flux density). The BH curve of FIG. 1 also shows that as magnetic field changes direction there is a “hysteresis” effect where the change in flux density lags behind the field strength. The amount of this hysteresis represents losses in the core and also is proportional to the susceptibility of the core to DC voltage saturation. Depending on the permeability of the core, the hysteresis effect changes. As can be seen from FIG. 1, an E-I core has the greatest hysteresis, whereas the continuous toroidal core has the least. This illustrates why the latter is so susceptible to DC voltage, such as a DC offset voltage.

With reference to FIG. 2, when a small DC offset voltage (such as 10-20 milli-volts) is applied to a toroidal core transformer the toroidal core transformer becomes partially saturated. If the DC offset voltage is positive, the saturation current occurs near the end of the positive half cycle as shown in FIG. 2. Conversely, if the DC offset voltage is negative, the saturation current occurs near the end of the negative half-cycle as also shown in FIG. 2. The DC offset voltage in FIG. 2 is exaggerated for better clarity.

### SUMMARY

This section provides a general summary of the disclosure, and is not a comprehensive disclosure of its full scope or all of its features.

In accordance with an aspect of the present disclosure, a DC offset voltage in an AC input voltage to a transformer and associated saturation current are eliminated by the placement of an anti-parallel diode pair circuit in series between a source of the AC input voltage and a primary winding of the transformer. The anti-parallel diode pair circuit has an input coupled to an output by parallel connected oppositely biased branch diode circuits. Each branch diode circuit has at least one diode where the diode of one such branch diode circuit is biased in one direction and the diode of the other such branch diode circuit is biased in an opposite direction and each branch diode circuit has the same number of diodes as the other branch diode circuit.

In an aspect, each branch diode circuit includes two diodes connected in series with each other with the diodes of one of the branch diode circuits biased in the one direction and the diodes of the other branch diode circuits biased in the opposite direction.

In an aspect, midpoints of the branch diode circuits are connected together.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a waveform diagram showing how permeability of a transformer core affects the relationship between magnetic field strength and magnetic flux density;

FIG. 2 is a waveform diagram showing where saturation current occurs in the positive and negative half cycles due to a small DC offset voltage applied to a toroidal transformer;

FIG. 3 is a simplified schematic of an anti-parallel diode pair circuit in accordance with an aspect of the present disclosure connected to a transformer;

FIG. 4 is a waveform diagram showing voltage applied to a transformer reduced by the diode voltage drop of diodes of the anti-parallel diode pair circuit of FIG. 3;

FIG. 5 is a waveform diagram showing transformer voltage as compare to applied line voltage at the positive zero crossing point of the sinewave for the case with no saturation current;

FIG. 6 is a waveform diagram showing transformer voltage as compare to applied line voltage at the positive zero crossing point of the sinewave for the case with saturation current;

FIG. 7 is a simplified schematic of a variation of the anti-parallel diode pair circuit of FIG. 3 in accordance with an aspect of the present disclosure; and

FIG. 8 is a simplified schematic showing the anti-parallel diode pair circuit connected between a source of AC voltage and a transformer of a power supply of audio equipment in accordance with an example embodiment of an aspect of the present disclosure.

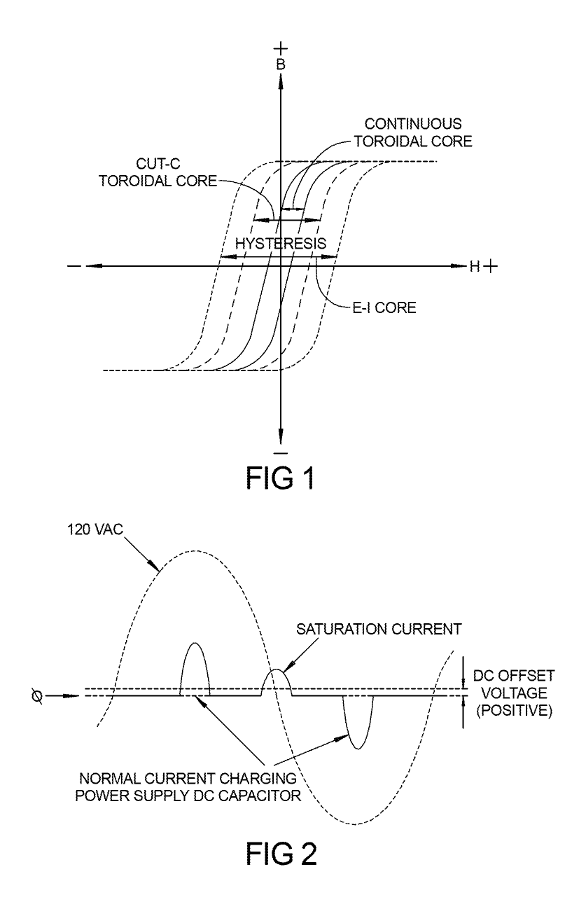

Corresponding reference numerals indicate corresponding parts throughout the several views of the drawings.

### DETAILED DESCRIPTION

Example embodiments will now be described more fully with reference to the accompanying drawings.

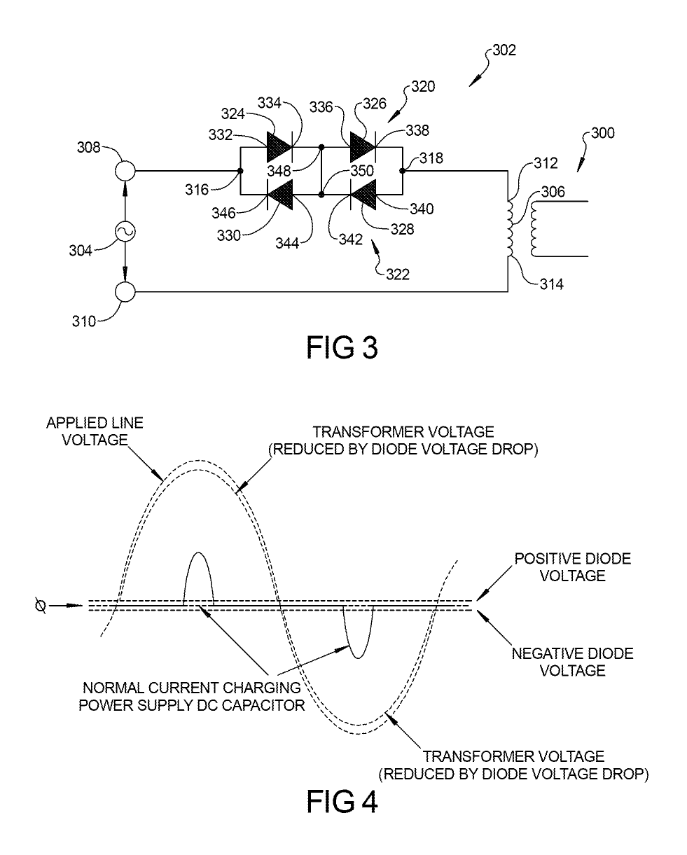

With reference to FIG. 3, in accordance with an aspect of the present disclosure, a DC offset voltage in an AC input voltage to a transformer 300 and associated saturation current of transformer 300 are eliminated by placing an anti-parallel diode pair circuit 302 in series between an AC input voltage source 304 to the transformer 300 and a primary winding 306 of transformer 300. In an example, input voltage source 304 is a source of 120 VAC having a hot side 308 and a common side 310. In this example, anti-parallel diode pair circuit 302 is in series between hot side 308 and a hot side 312 of primary winding 306 of transformer 300. It should be understood that input voltage source can be other than a source of 120 VAC, for example 220 VAC or 240 VAC such as used in many European countries. It should also be understood that input voltage source 304 could be floating with common side 310 then being a negative side and anti-parallel diode pair circuit 302 could then alternatively be in series between side 310 of input voltage source 304 and a negative side 314 of primary winding 306 of transformer 300.

As used herein, an anti-parallel diode pair circuit is a circuit having parallel connected oppositely biased branch diode circuits with each branch diode circuit having one or more diodes where the diode (or diodes) in one branch diode circuit are oppositely biased to the diode (or diodes) in the other branch diode circuit. That is, the diode (or diodes) in one branch circuit are biased in one direction and the diode (or diodes) in the other branch circuit are biased in the opposite direction. The branch diode circuits have the same number of diodes. These branch diode circuits are referred to together herein as oppositely biased branch diode circuits.

With reference to the example shown FIG. 3, anti-parallel diode pair circuit 302 has an input 316 coupled to an output 318 by oppositely biased branch diode circuits 320, 322 that are connected in parallel with each other and that are biased in opposite directions. Input 316 is coupled to hot side 308 of voltage source 304 and output 318 is coupled to hot side 312 of primary winding 306 of transformer 300. In this example, each branch diode circuit 320, 322 has two diodes. Branch diode circuit 320 has diodes 324, 326 that are connected in series with each other and biased in one direction. More specifically, an anode 332 of diode 324 is coupled to input 316 of anti-parallel diode pair circuit 302 and a cathode 334 of diode 324 is coupled to an anode 336 of diode 326. A cathode 338 of diode 326 is coupled to output 318 of anti-parallel diode pair circuit 302. Branch diode circuit 322 has diodes 328, 330 that are connected in series with each other and biased in a direction that is opposite the direction that diodes 324, 326 of branch diode circuit 320 are biased. More specifically, an anode 340 of diode 328 is coupled to output 318 of anti-parallel diode pair circuit 302 and a cathode 342 of diode 328 is coupled to anode 344 of diode 330. A cathode 346 of diode 330 is coupled to input 316 of anti-parallel diode pair circuit 302. A midpoint 348 of branch diode circuit 320 which in the example of FIG. 3 is a junction of cathode 334 of diode 324 and anode 336 of diode 326 is coupled to a midpoint 350 of branch diode circuit 322, which in the example of FIG. 3 is a junction of cathode 342 of diode 328 and anode 344 of diode 330.

With reference to FIGS. 4-6, how the anti-parallel diode pair circuit, such as anti-parallel diode pair circuit 302, functions to remove the DC offset voltage on the AC voltage source, such as voltage source 304, and avoid transformer saturation is discussed. Since the diodes in the anti-parallel diode pair circuit are in series with the AC voltage source to the transformer, such as transformer 300, then the voltage applied to the primary winding of the transformer, such as primary winding 306 of transformer 300, will be reduced by the diode voltage drop. This applies to both halves of the sinewave of AC voltage source and is shown in FIG. 4.

It should be understood that if there was no saturation current, then the voltage applied to the primary winding of the transformer would simply be reduced by the diode voltage drop for both halves of the sinewave. Assuming that the diode characteristics are equally or very nearly equally matched, then both halves of the sinewave would be reduced by an equal amount. Therefore, any DC offset voltage would still be present in the voltage applied to the primary winding of the transformer. FIG. 5 shows the transformer voltage (which in this context is the primary winding voltage) as compared to the applied line voltage at the positive zero crossing point of the sinewave for the case with no saturation current.

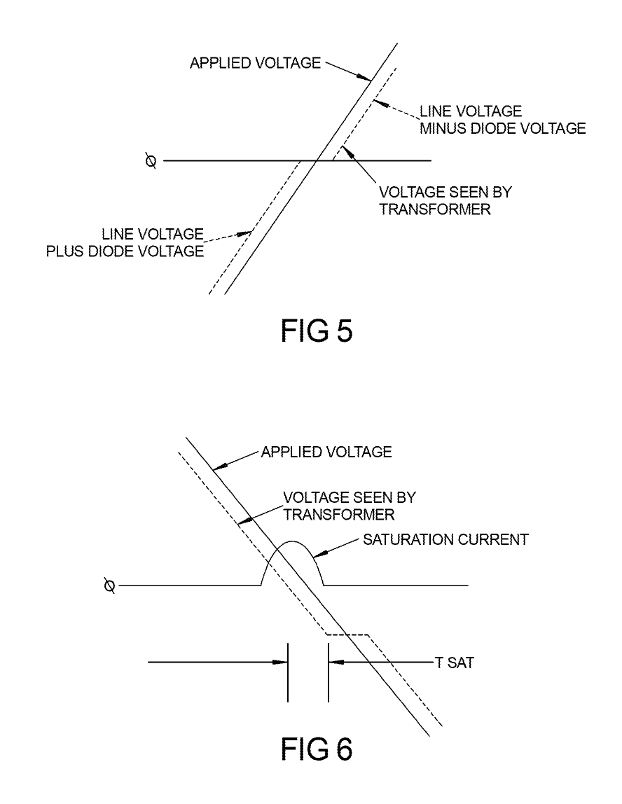

For the case with saturation current the conditions are quite different. FIG. 6 shows a negative zero cross point for this case. For small DC offset voltages, the saturation current occurs at a point very near the end of the half cycle, the point where the integral of the voltage (equivalent to flux) for the half cycle plus the DC offset finally exceeds the normal flux limit. For a positive DC offset this would occur on the positive half cycle and conversely for negative DC offset. Also, the saturation current continues to flow for a brief period of time after the voltage crosses zero and goes negative. Mathematically, this is necessarily true since the excess peak flux which exists when the voltage reaches zero can only be reduced back to normal by integrating an opposite polarity voltage. Since this saturation current also flows through the diodes of the anti-parallel diode pair circuit, for example, anti-parallel diode pair circuit 302, and does not reverse direction at the zero cross point, but rather sometime after the zero cross point (when the saturation current finally falls to zero), then a positive voltage must be removed from the negative side of the applied voltage waveform during this period. This effectively makes the average negative half cycle more negative, if only by a small amount.

It can be seen that the effect of this voltage on the negative half cycle will compensate for the positive DC offset voltage to some degree. This can be determined by calculating the equivalent volt-seconds of each. The volt-seconds for the DC offset voltage is simply the amount of DC offset voltage multiplied by one full cycle period time, and the volt-seconds for the saturation current effect is the diode voltage drop multiplied by the time needed for the saturation current to fall from its peak value to zero (labeled Tsat in FIG. 6). In fact, the compensation effect is greater than what it first seems since the voltage added to the effected half cycle (the half cycle opposite the saturation half cycle) “replaces” an opposite polarity voltage that would have otherwise been added to that half cycle. This effectively doubles the compensating effect.

The above analysis implies that some finite amount of saturation current must continue to flow to balance any DC offset voltage which is present in the applied line voltage. A balance equation can be used to determine how long the saturation current must flow. Since the effect of the “Tsat” time is doubled as described above and Tsat in FIG. 6 represents ½ the total saturation current time, the net effect can is canceled and the following equation below represents the total time that saturation current flows: T sat*V diode=T period*V dc offset. Taking as an example a case where 10 milli-volts of DC offset exists and assuming 1.4 volts for the diode drop (since two diodes are connected in series for each diode circuit branch in the example anti-parallel diode pair circuit 302 of FIG. 3):
Tsat*1.4 volts=16.6 milliseconds*10 millivolts; and
Tsat=118 microseconds
   This period of time is small enough that only a few milliamps of saturation current flows—less than the magnetizing current of even a small transformer, and therefore quite insignificant.

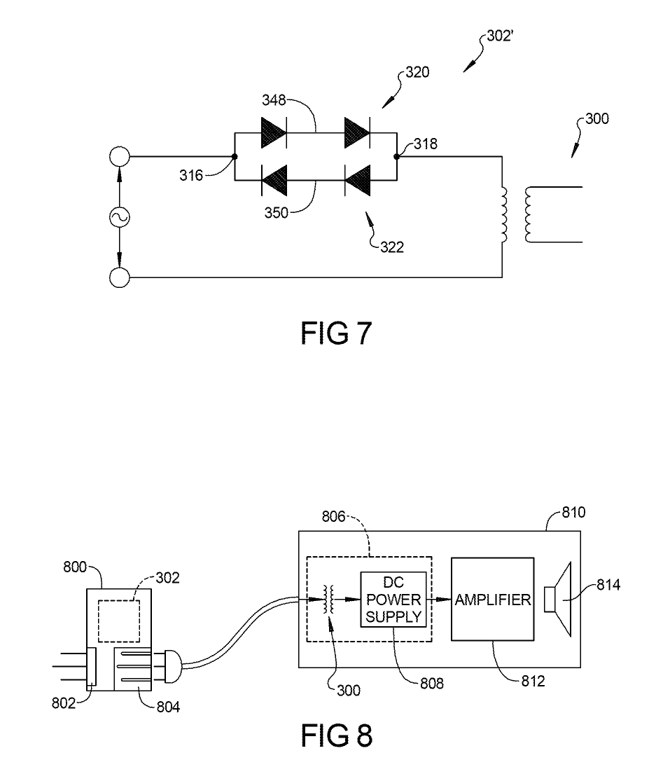

In accordance with another aspect of the present disclosure, the midpoints of each branch diode circuit of the of anti-parallel diode pair circuit, such as midpoints 348, 350 of branch diode circuits 320, 322 of anti-parallel diode pair circuit 302 of FIG. 3, are connected together as shown in the example embodiment of FIG. 3. Although this has no effect on the behavior of the anti-parallel diode pair circuit in normal operation it does afford a practical advantage in the event of a diode failure. Using as an example anti-parallel diode pair circuit 302, since the typical failure mode of a diode is to short circuit, if any one diode fails, the midpoint connection will effectively short the opposite diode in the other branch diode circuit. There will now be only one diode in each branch diode circuit 320, 322 to provide the function of eliminating the DC offset voltage and thus transformer saturation so anti-parallel diode pair circuit 302 will not be as effective as with two diodes in each branch diode circuit. But this is preferred over having one diode in one branch diode circuit and two diodes in the opposite branch diode circuit which would be the case if the midpoints 348, 350 of the branch diode circuits 320, 322 were not connected. In such a case, a large DC offset would be created and seen by the transformer 300. This DC offset would be even more severe than the original DC offset present in the AC source voltage for which anti-parallel diode pair circuit 302 is intended to compensate. It should be understood, however, that the midpoints of the branch diode circuits of the anti-parallel diode pair circuit need not be connected together. FIG. 7 shows an anti-parallel diode pair circuit 302′ in which the midpoints 348, 350 of the branch diode circuits 320, 322 are not connected together. Anti-parallel diode pair circuit 302′ is otherwise the same as anti-parallel diode pair circuit 302 of FIG. 3.

In an aspect and with reference to FIG. 8 and using anti-parallel diode circuit 302 as an example, the anti-parallel diode pair circuit 302 is packaged such as in a box 800 having a standard 120 VAC plug 802 and also a standard 120 VAC receptacle 804 with the anti-parallel diode pair circuit 302 in series in the AC hot line between them. The box 800 is plugged into a wall socket (not shown) that provides 120 VAC and which is input voltage source 304. A power supply 806 of the device to be powered such as audio equipment 810 in the example of FIG. 8 is then plugged into the receptacle 804 of the box 800. Illustratively power supply 806 includes transformer 300 and a DC power supply 808. Audio equipment 810 illustratively includes an amplifier 812 powered by DC power supply 808 and amplifier 812 drives a speaker 814.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

What is claimed is:

1. A method of eliminating a DC offset voltage in an AC input voltage to a transformer and associated saturation current of the transformer, comprising:
placing an anti-parallel diode pair circuit in series between a source of the AC input voltage and a primary winding of the transformer.

2. The method of claim 1 wherein placing the anti-parallel diode pair circuit includes placing an anti-parallel diode pair circuit having parallel connected oppositely biased branch diode circuits with each branch diode circuit having at least one diode where the diode of one such branch diode circuit is biased in one direction and the diode of the other such branch diode circuit is biased in an opposite direction and each branch diode circuit has the same number of diodes as the other branch diode circuit.

3. The method of claim 2 wherein placing as the anti-parallel diode pair circuit includes placing an anti-parallel diode pair circuit having parallel connected oppositely biased branch diode circuit where each branch diode circuit includes two diodes connected in series with each other with the diodes of one of the branch diode circuits biased in the one direction and the diodes of the other branch diode circuits biased in the opposite direction.

4. The method of claim 3 wherein placing as the anti-parallel diode pair circuit includes placing an anti-parallel diode pair circuit having midpoints of the branch diode circuits connected together.

5. An anti-parallel diode pair circuit, comprising:
an input coupled to an output by parallel connected branch diode circuits; and
each branch diode circuit having at least one diode where the diode of one such branch diode circuit is biased in one direction and the diode of the other such branch diode circuit is biased in an opposite direction and each branch diode circuit has the same number of diodes as the other branch diode circuit.

6. The anti-parallel diode pair circuit of claim 5, wherein each branch diode circuit includes two diodes connected in series with each other with the diodes of one of the branch diode circuits biased in the one direction and the diodes of the other branch diode circuits biased in the opposite direction.

7. The anti-parallel diode pair circuit of claim 6 wherein midpoints of the branch diode circuits are connected together.

8. In combination, a transformer and anti-parallel diode pair circuit, comprising:
the anti-parallel diode pair circuit coupled in series between a primary winding of the transformer and a source of an AC input voltage to the transformer.

9. The combination of claim 8 wherein the anti-parallel diode pair circuit includes an input coupled to an output by parallel connected branch diode circuits and each branch diode circuit having at least one diode where the diode of one such branch diode circuit is biased in one direction and the diode of the other such branch diode circuit is biased in an opposite direction and each branch diode circuit has the same number of diodes as the other branch diode circuit.

10. The combination of claim 9 wherein each branch diode circuit includes two diodes connected in series with each other with the diodes of one of the branch diode circuits biased in the one direction and the diodes of the other branch diode circuits biased in the opposite direction.

11. The combination of claim 10 wherein midpoints of the branch diode circuits are connected together.
